(19) United States
(12) Patent Application Publication
(10) Pub. No.: US 2024/0363357 A1
(43) Pub. Date: Oct. 31, 2024

(54) METHODS FOR BOW COMPENSATION USING TENSILE NITRIDE

(71) Applicant: Applied Materials, Inc., Santa Clara, CA (US)

(72) Inventors: David H. Collins, Delmar, NY (US); Nobuyuki Takahashi, Slingerlands, NY (US); Pin Hian Lee, Mechanicville, NY (US); Rio Soedibyo, Ballston Spa, NY (US); Sanggil Bae, Clifton Park, NY (US); Houssam Lazkani, Glenville, NY (US); Songkram Sonny Srivathanakul, Waterford, NY (US); Raman Gaire, Mechanicville, NY (US); Gopal Bajaj, Ballston Lake, NY (US)

(73) Assignee: Applied Materials, Inc., Santa Clara, CA (US)

(21) Appl. No.: 18/631,384

(22) Filed: Apr. 10, 2024

Related U.S. Application Data
(60) Provisional application No. 63/462,315, filed on Apr. 27, 2023.

(51) Int. Cl. H01L 21/311; H01L 21/02; H01L 23/00

(52) U.S. Cl. CPC H01L 21/31105; H01L 21/0217; H01L 21/02274; H01L 23/562

(57) ABSTRACT

Embodiments of the present technology may include semiconductor processing methods. The methods may include providing deposition precursors to a processing region of a semiconductor processing chamber. The deposition precursors may include a silicon-containing precursor and a nitrogen-containing precursor. A substrate including one or more materials may be disposed within the processing region. The substrate may be characterized by a first bowing of the substrate. The methods may include generating plasma effluents of the deposition precursors. The methods may include forming a layer of silicon-and-nitrogen-containing material on the substrate. The layer of silicon-and-nitrogen-containing material may be characterized by a tensile stress. Subsequent forming the layer of silicon-and-nitrogen-containing material, the substrate may be characterized by a second bowing of the substrate that is less than the first bowing of the substrate.

### CROSS-REFERENCE TO RELATED APPLICATIONS

This application claims the benefit of, and priority to U.S. Provisional Application Ser. No. 63/462,315, filed Apr. 27, 2023, which is hereby incorporated by reference in its entirety for all purposes.

### TECHNICAL FIELD

The present technology relates to semiconductor systems and processes. More specifically, the present technology relates to deposition systems and methods in which a tensile silicon nitride layer may be formed.

### BACKGROUND

Integrated circuits are made possible by processes which produce intricately patterned material layers on substrate surfaces. Producing patterned material on a substrate requires controlled methods of formation and removal of exposed material. Material characteristics may affect how the device operates, and may also affect how the films are removed relative to one another. During formation and removal, different stresses may be imparted to the substrate. If the overall stress imparted to the substrate becomes too tensile or too compressive, methods of formation and removal of exposed material may become less controlled.

Thus, there is a need for improved systems and methods that can be used to produce high quality devices and structures. These and other needs are addressed by the present technology.

### SUMMARY

Embodiments of the present technology may include semiconductor processing methods. The methods may include providing deposition precursors to a processing region of a semiconductor processing chamber. The deposition precursors may include a silicon-containing precursor and a nitrogen-containing precursor. A substrate including one or more materials may be disposed within the processing region. The substrate may be characterized by a first bowing of the substrate. The methods may include generating plasma effluents of the deposition precursors. The methods may include forming a layer of silicon-and-nitrogen-containing material on the substrate. The layer of silicon-and-nitrogen-containing material may be characterized by a tensile stress. Subsequent forming the layer of silicon-and-nitrogen-containing material, the substrate may be characterized by a second bowing of the substrate that is less compressive than the first bowing of the substrate.

In embodiments, the one or more materials may include alternating pairs of a silicon-containing material and a silicon-and-germanium-containing material. The layer of silicon-and-nitrogen-containing material may be formed on the alternating pairs of the silicon-containing material and the silicon-and-germanium-containing material. The one or more materials may include greater than 36 alternating pairs of the silicon-containing material and the silicon-and-germanium-containing material. A thickness of the silicon-and-germanium-containing material may be greater than or about 5 nm. The first bowing of the substrate may be greater than or about 200 μm. The methods may include treating the layer of silicon-and-nitrogen-containing material with a treatment plasma to increase the tensile stress of the layer of silicon-and-nitrogen-containing material. A thickness of the layer of silicon-and-nitrogen-containing material may be greater than or about 50 nm. The methods may include depositing one or more additional layers of material on the layer of silicon-and-nitrogen-containing material. The one or more additional layers of material may define a patterning stack. The patterning stack may include a second layer of silicon-and-nitrogen-containing material. The second layer of silicon-and-nitrogen-containing material may be characterized by a thickness greater than the thickness of the layer of silicon-and-nitrogen-containing material. The methods may include etching one or more features through the one or more materials on the substrate. The etching may consume the layer of silicon-and-nitrogen-containing material. The etching may reduce a compressive stress of the substrate and the one or more materials.

Some embodiments of the present technology may encompass semiconductor processing methods. The methods may include providing a substrate to a processing region of a semiconductor processing chamber. The substrate may include alternating pairs of a silicon-containing material and a silicon-and-germanium-containing material. The substrate may be characterized by a first bowing of the substrate. The methods may include forming a patterning stack including one or more layers of material on the alternating pairs of the silicon-containing material and the silicon-and-germanium-containing material. The one or more layers of material may include at least one layer of silicon-and-nitrogen-containing material characterized by a tensile stress. Subsequent to forming the patterning stack, the substrate may be characterized by a second bowing of the substrate that may be less than the first bowing of the substrate. The methods may include etching one or more features through the alternating pairs of the silicon-containing material and the silicon-and-germanium-containing material. The etching may remove at least a portion of the patterning stack. Subsequent to etching, the substrate may be characterized by a third bowing of the substrate that may be less than the first bowing of the substrate.

In embodiments, the substrate may include greater than 50 alternating pairs of the silicon-containing material and the silicon-and-germanium-containing material. A thickness of the silicon-and-germanium-containing material may be less than or about 30 nm. The first bowing of the substrate may be greater than or about 275 μm. The patterning stack may include a first layer of silicon-and-nitrogen-containing material disposed on the alternating pairs. The patterning stack may include a layer of silicon-containing material disposed on the first layer of silicon-and-nitrogen-containing material. The patterning stack may include a second layer of silicon-and-nitrogen-containing material disposed on the layer of silicon-containing material. The patterning stack may include a layer of carbon-containing material disposed on the second layer of silicon-and-nitrogen-containing material. The patterning stack may include a third layer of silicon-and-nitrogen-containing material disposed on the layer of carbon-containing material. The second bowing of the substrate may be less than or about 175 μm. A compressive stress imparted by the alternating pairs of the silicon-containing material and the silicon-and-germanium-containing material may reduce while etching the one or more features. The tensile stress imparted by the at least one layer of silicon-and-nitrogen-containing material may reduce while etching removes at least the portion of the patterning stack.

Some embodiments of the present technology may encompass semiconductor structures. The structure may include a substrate. The structure may include alternating pairs of a silicon-containing material and a silicon-and-germanium-containing material disposed on the substrate. The structure may include a patterning stack comprising at least one layer of silicon-and-nitrogen-containing material characterized by a compressive stress disposed on the alternating pairs. The semiconductor structure may be characterized by a bowing of the substrate of less than or about −200 nm.

In embodiments, the patterning stack may include a first layer of silicon-and-nitrogen-containing material disposed on the alternating pairs. The patterning stack may include a layer of silicon-containing material disposed on the first layer of silicon-and-nitrogen-containing material. The patterning stack may include a second layer of silicon-and-nitrogen-containing material disposed on the layer of silicon-containing material. The patterning stack may include a layer of carbon-containing material disposed on the second layer of silicon-and-nitrogen-containing material. The patterning stack may include a third layer of silicon-and-nitrogen-containing material disposed on the layer of carbon-containing material.

Such technology may provide numerous benefits over conventional systems and methods of treating substrate bowing. For example, using silicon-and-nitrogen-containing material characterized by tensile stress may form material in a patterning stack that is removed during subsequent etching operations. Thus, as the compressive stress from materials on the substrate is reduced, the tensile stress from the silicon-and-nitrogen-containing material may reduce to maintain a desired amount of bow compensation. Additionally, the present technology may avoid the need for frontside or backside compensation layers to be deposited and subsequently removed. With less deposition and removal steps, throughput may be increased, and queue times may be reduced. Embodiments of the present technology, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

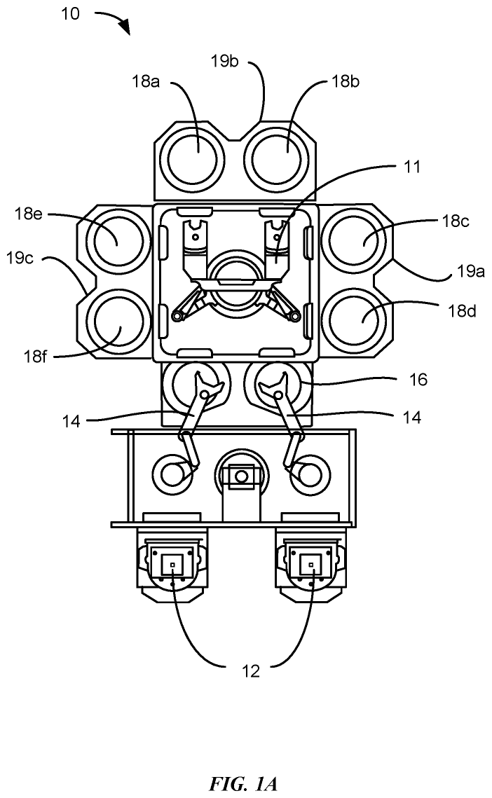

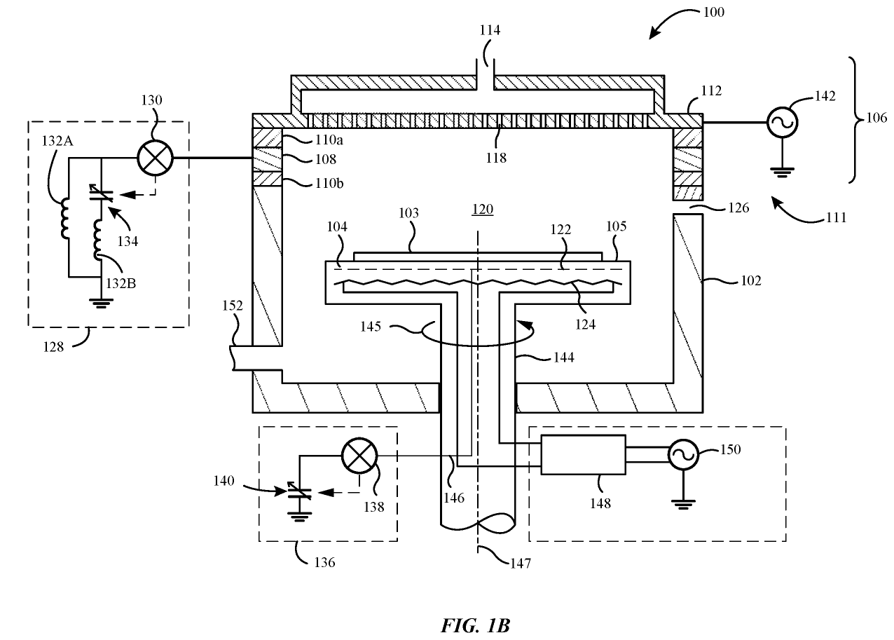

FIG. 1A shows a top plan view of an exemplary processing system according to some embodiments of the present technology.

FIG. 1B shows a schematic cross-sectional view of an exemplary processing system according to some embodiments of the present technology.

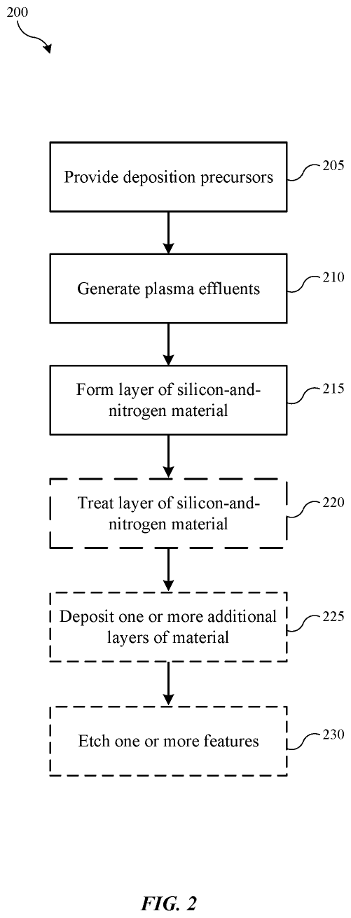

FIG. 2 shows operations of an exemplary method of semiconductor processing according to some embodiments of the present technology.

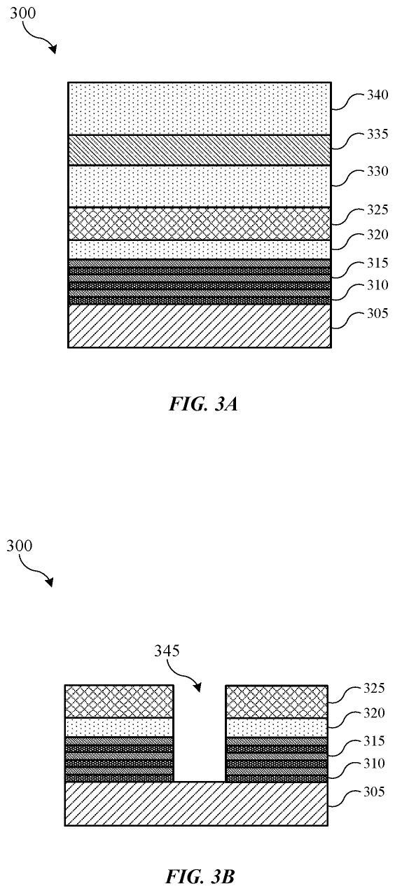

FIGS. 3A-B show a cross-sectional views of exemplary semiconductor structures according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In dynamic random-access memory (DRAM) structures, such as 3D DRAM, alternating layers of material may be formed on a substrate. The alternating layers of material may include alternating pairs of a silicon-containing material and a silicon-and-germanium-containing material. As the number of layers increase, so does the challenge to maintain defect free epitaxial growth and minimized bowing of the substrate. In one example, as the number of layers silicon-and-germanium-containing material increases, or as the thickness of the materials increase, increased compressive stress may cause the substrate to bow. If the substrate becomes too bowed, the substrate may break and/or downstream operations may be frustrated. For example, many downstream operations have bow limitations, including deposition, lithography, and etch operations. Accordingly, processes to combat substrate bow are necessary to perform downstream operations.

In conventional processes, one or more layers of material may be deposited on a frontside or backside of the substrate to compensate for the bowing. Compensation materials, either frontside or backside, may exhibit stress hysteresis. Additionally, compensation materials may lead to material defects as well as high thicknesses to compensate for substrate bowing. Furthermore, compensation materials ultimately need to be removed, which introduces additional processing to remove the materials. The present technology may instead form a patterning stack on the substrate that introduces tensile stress to the substrate to combat the compressive stress of material formed on the substrate. More specifically, the present technology includes silicon-and-nitrogen-containing material in the patterning stack that is characterized by tensile stress. The amount of silicon-and-nitrogen-containing material is selected to reduce the bowing in the substrate. As materials on the substrate are etched in downstream operations, compressive stress imparted by these materials may reduce. Similarly, as the etch proceeds, portions of the patterning stack, including the silicon-and-nitrogen-containing material, may be removed and the tensile stress may be reduced. Accordingly, as the compressive stress reduces, so does the tensile stress, which maintains bowing in the substrate at a desired amount. Since the patterning stack including the silicon-and-nitrogen-containing material is removed during the etch, complexity of the bow compensation is reduced, a risk wafer bow inversion is minimized, and additional processing to remove the bow compensation material is reduced and/or eliminated.

After describing general aspects of a chamber configured to perform operations according to embodiments of the present technology in which plasma processing may be performed, specific methodology and component configurations may be discussed. It is to be understood that the present technology is not intended to be limited to the specific films and processing discussed, as the techniques described may be used to improve a number of film formation processes, and may be applicable to a variety of semiconductor processing chambers and operations.

FIG. 1A shows a top plan view of one embodiment of a processing system 10 of deposition, treating, etching, baking, and curing chambers according to embodiments. In the figure, a pair of front opening unified pods 12 supply substrates of a variety of sizes that are received by robotic arms 14 and placed into a low pressure holding area 16 before being placed into one of the semiconductor processing chambers 18a-f, positioned in tandem sections 19a-c. A second robotic arm 11 may be used to transport the substrate wafers from the holding area 16 to the semiconductor processing chambers 18a-f and back. Each semiconductor processing chamber 18a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, plasma treatments, annealing, ashing, etc.

The semiconductor processing chambers 18a-f may include one or more system components for depositing, plasma treating, curing and/or etching a dielectric or other film on the substrate. In one configuration, two pairs of the semiconductor processing chambers, e.g., 18c-d and 18e-f, may be used to deposit dielectric material on the substrate, and the third pair of semiconductor processing chambers, e.g., 18a-b, may be used to treat the deposited dielectric. In another configuration, all three pairs of chambers, e.g., 18a-f, may be configured to deposit and treat stacks of alternating dielectric films on the substrate. Any one or more of the processes described may be carried out in chambers separated from the fabrication system shown in different embodiments. It will be appreciated that additional configurations of deposition, treating, etching, annealing, and curing chambers for dielectric films are contemplated by system 10.

FIG. 1B shows a cross-sectional view of an exemplary semiconductor processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form tensile nitride films according to some embodiments of the present technology, although it is to be understood that the methods may similarly be performed in any chamber within which film formation may occur. The semiconductor processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the semiconductor processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the semiconductor processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the semiconductor processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1B, or the gas distributor 112 may be coupled with ground in some embodiments.

The first electrode 108 may be coupled with a first tuning circuit 128 that may control a ground pathway of the semiconductor processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1B may be used with any semiconductor processing chamber for plasma or thermal processing. In operation, the semiconductor processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the semiconductor processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

FIG. 2 shows exemplary operations in a processing method 200 according to some embodiments of the present technology. The method may be performed in a variety of semiconductor processing chambers, including semiconductor processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

Method 200 may include additional operations prior to initiation of the listed operations. For example, additional processing operations may include forming structures on a substrate, which may include both forming and removing material. Prior processing operations may be performed in the chamber in which method 200 may be performed, or processing may be performed in one or more other semiconductor processing chambers prior to delivering the substrate into the semiconductor processing chamber in which method 200 may be performed. Regardless, method 200 may optionally include delivering a substrate to a processing region of a semiconductor processing chamber, such as semiconductor processing chamber 100 described above, or other chambers that may include components as described above. The substrate may be deposited on a substrate support, which may be a pedestal such as substrate support 104, and which may reside in a processing region of the chamber, such as processing volume 120 described above.

In embodiments, prior processing may form one or more materials on the substrate. For example, the substrate may previously be processed alternating pairs of a silicon-containing material and a silicon-and-germanium-containing material, which may be applicable to formation of 3D DRAM structures. However, as the number of alternating layers of silicon-containing material and silicon-and-germanium-containing material increase, the substrate may be characterized by an increased bow. With an increased bow in the substrate, many downstream operations may be frustrated, and some tools may not be able to process the substrate. Conventional technologies have typically addressed bowing in the substrate by depositing materials on a frontside or backside of the substrate that may later be removed. However, these conventional technologies require additional formation and removal operations that reduce throughput and may lead to defectivity in the structure due. Accordingly, method 200 may form tensile silicon-and-nitrogen-containing material to combat and reduce bowing in the substrate to allow for further processing to continue. Additionally, the present technology may form tensile silicon-and-nitrogen-containing material in a patterning stack that is consumed during etching of, for example, features through the alternating layers of silicon-containing material and silicon-and-germanium-containing material. The consumption of the tensile silicon-and-nitrogen-containing material may reduce the overall tensile stress imparted to the substrate as compressive stress imparted by the alternating layers of silicon-containing material and silicon-and-germanium-containing material is reduced during etching.

Depending on the materials formed on the substrate, such as the number of materials and the thicknesses thereof, the substrate may be characterized by a first bowing of the substrate. In embodiments, the first bowing of the substrate may be greater than or about greater than or about 150 μm, greater than or about 175 μm, greater than or about 200 μm, greater than or about 225 μm, greater than or about 250 μm, greater than or about 275 μm, greater than or about 300 μm, greater than or about 350 μm, greater than or about 400 μm, greater than or about 450 μm, greater than or about 500 μm, greater than or about 550 μm, greater than or about 600 μm, greater than or about 650 μm, greater than or about 675 μm, greater than or about 700 μm, or more. In embodiments, the silicon-and-germanium-containing material may impart compressive stress that causes the bowing of the substrate. Therefore, the first bowing may be correlated to the number of layers of silicon-and-germanium-containing material and the thicknesses thereof.

In forming a patterning stack including a layer of silicon-and-nitrogen-containing material characterized by tensile stress, method 200 may include flowing deposition precursors into a processing region of a semiconductor processing chamber at operation 205. The deposition precursors may include at least one silicon-containing precursor and at least one nitrogen-containing precursor. The silicon-containing precursor may be or include silane and disilane, among other silicon containing precursors useful in semiconductor processing. The nitrogen-containing precursor may be or include ammonia (NH₃) and mixtures of molecular nitrogen and hydrogen (N₂+H₂), among other nitrogen-containing precursors useful in semiconductor processing. The deposition precursors may also include at least one carrier gas. Embodiments of carrier gases may include molecular nitrogen (N₂), helium, xenon, or argon, among other carrier gases useful in semiconductor processing.

Embodiments of method 200 may further include generating plasma effluents of the deposition precursors in the processing region of the semiconductor processing chamber at operation 210. The deposition plasma may be generated by delivering plasma power to the deposition precursors that have flowed into the processing region. In some embodiments, the plasma power may be delivered by a source of radio frequency (RF) power that is electrically coupled to at least one electrode within the semiconductor processing chamber. In embodiments, the RF power source may deliver power to the at least one electrode, which creates an electric field in the processing region of the semiconductor processing chamber that energizes the deposition precursors to form the deposition plasma. The plasma power delivered to the deposition precursors may be less than or about 60 Watts, less than or about 55 Watts, less than or about 50 Watts, less than or about 45 Watts, less than or about 40 Watts, less than or about 35 Watts, less than or about 30 Watts, or less. The frequency of the RF power delivered to the deposition precursors may be 13.56 MHz in one non-limiting example. In some embodiments, the plasma power delivered to the deposition precursors may be supplied continuously, while in additional embodiments, the plasma power may be pulsed. In pulsed embodiments, the delivered RF plasma power may have a pulsing frequency that may be less than or about 10 kHz, and may be less than or about 9 kHz, less than or about 8 kHz, less than or about 7 kHz, less than or about 6 kHz, less than or about 5 kHz, less than or about 4 kHz, less than or about 3 kHz, less than or about 2 kHz, less than or about 1 kHz, or less. In some pulsed embodiments, the off portion of the plasma power's duty cycle may allow more diffusion of the plasma effluents in the as-deposited silicon-and-nitrogen-containing material. The longer diffusion time for the plasma effluents may form a more uniform as-deposited material.

Embodiments of processing method 200 may further include depositing a layer silicon-and-nitrogen-containing material on the substrate in the semiconductor processing chamber from the deposition plasma at operation 215. In embodiments, the as-deposited layer of silicon-and-nitrogen-containing material may be silicon nitride. The layer of silicon-and-nitrogen-containing material may be formed on the alternating pairs of silicon-containing material and silicon-and-germanium-containing material. Additionally, the layer of silicon-and-nitrogen-containing material may be one layer of a patterning stack formed on the one or more materials on the substrate, such as the alternating pairs of silicon-containing material and silicon-and-germanium-containing material. In embodiments, depending on the bow imparted to the substrate by the materials, the patterning stack may include one or more layers of silicon-and-nitrogen-containing material to combat the bow. For example, the patterning stack may include additional patterning material, such as silicon-containing material or carbon-containing material, in addition to one or more layers of tensile silicon-and-nitrogen-containing material.

In embodiments, the deposition of the silicon-and-nitrogen-containing material on the substrate may be conducted at a deposition temperature that influences the deposition rate of the material. For example, the processing region of the semiconductor processing chamber may be characterized by a deposition temperature less than or about 550° C., less than or about 500° C., less than or about 475° C., less than or about 450° C., less than or about 425° C., less than or about 400° C., less than or about 375° C., less than or about 350° C., or less than or about 300° C., or less. By depositing at temperatures below or about 500° C., the present technology may protect device thermal budgets. The silicon-and-nitrogen-containing material may be deposited at a deposition rate less than or about 2 nm/second, less than or about 1.5 nm/second, less than or about 1.2 nm/second, less than or about 1 nm/second, less than or about 0.8 nm/second, less than or about 0.5 nm/second, less than or about 0.2 nm/second, or less.

A discussed further below, a thickness of the as-deposited layer of silicon-and-nitrogen-containing material on the substrate may be dependent on the stress needed to compensate for the bowing of the substrate imparted by the one or more materials deposited on the substrate. In embodiments, the thickness of the as-deposited layer of silicon-and-nitrogen-containing material may be greater than or about 10 nm, greater than or about 15 nm, greater than or about 20 nm, greater than or about 25 nm, greater than or about 30 nm, greater than or about 35 nm, greater than or about 50 nm, greater than or about 75 nm, greater than or about 100 nm, greater than or about 125 nm, greater than or about 150 nm, greater than or about 175 nm, greater than or about 200 nm, or more. However, the method 200 may include multiple cycles to deposit the layer of silicon-and-nitrogen-containing material. For example, as further discussed below, a treatment may be performed after depositing a portion of the layer of silicon-and-nitrogen material. Method 200 may include multiple cycles of deposition and treatment to form the entire layer of silicon-and-nitrogen-containing material. In embodiments, the thickness of the as-deposited layer of silicon-and-nitrogen-containing material after one cycle may be greater than or about 1 nm, greater than or about 1.5 nm, greater than or about 2 nm, greater than or about 2.5 nm, greater than or about 3 nm, greater than or about 3.5 nm, greater than or about 5 nm, greater than or about 7.5 nm, greater than or about 10 nm, greater than or about 12.5 nm, greater than or about 15 nm, greater than or about 17.5 nm, greater than or about 20 nm, or more. Accordingly, in embodiments, each cycle of the deposition operation may take less than or about 100 seconds, less than or about 75 seconds, less than or about 60 seconds, less than or about 30 seconds, less than or about 15 seconds, less than or about 10 seconds, less than or about 5 seconds, less than or about 2 seconds, less than or about 1 second, or less.

While the deposited layer of silicon-and-nitrogen-containing material may be characterized by a tensile stress, additional processing may further increase the tensile stress of the layer of silicon-and-nitrogen-containing material. Accordingly, method 200 may include a treatment to increase tensile stress of the layer of silicon-and-nitrogen-containing material. The treatment operation may include flowing one or more treatment precursors into the processing region of a semiconductor processing chamber at optional operation 220. In embodiments, the method 200 may include performing a purge operation subsequent deposition and prior to the treatment, which may limit particle deposition on substrate. The treatment precursors may include a nitrogen-containing precursor, such as N₂, along with an inert gas precursor such as helium, argon, xenon, or neon. In embodiments, the treatment precursors may include some or all of the carrier gases that were also used as deposition precursors. For example, embodiments may include a reduction or stoppage in the flow of the silicon-containing and the nitrogen-containing deposition precursors used during the deposition operation while continuing to flow at least one of the carrier gases in the deposition precursors. In embodiments, the flow rate of the carrier gases may be increased during the transition from the deposition operation to the treatment operation.

Embodiments of processing method 200 may further include generating plasma effluents of the treatment precursor in the processing region of the semiconductor processing chamber. The plasma effluents of the treatment precursor may be generated by delivering plasma power to the treatment precursor that has flowed into the processing region. In some embodiments, the treatment plasma power may be delivered by the same source of radio frequency (RF) power, and through the same system electrodes, used to deliver the deposition plasma power. In embodiments, the treatment plasma power may be greater than the deposition plasma power that energizes the deposition plasma. In embodiments, the treatment plasma power may be greater than 60 W, greater than or about 70 W, greater than or about 80 W, greater than or about 90 W, greater than or about 100 W, greater than or about 110 W, greater than or about 120 W, greater than or about 130 W, greater than or about 140 W, greater than or about 150 W, or more. Increasing the plasma power may increase the dissociation and available radicals for bombardment and distribution within the film. The frequency of the RF power delivered to the treatment precursors may be 13.56 MHz in one non-limiting example. In some embodiments, the plasma power delivered to the treatment precursors may be supplied continuously, while in additional embodiments, the plasma power may be pulsed.

The plasma power may be delivered as a continuous wave during the transition from the deposition to the treatment plasma. This may reduce the time for each deposition and treatment cycle to form the tensile-stressed, silicon-and-nitrogen-containing layer. Where several deposition and treatment cycles are performed to complete the formation of the layer, the cumulative reduction in processing time can be substantial. In embodiments, the increase in plasma power during the treatment operation may also increase the tensile stress level in the fully-formed silicon-and-nitrogen-containing layer.

Processing method 200 may further include treating the as-deposited silicon-and-nitrogen-containing material on the substrate in the semiconductor processing chamber with the treatment plasma at optional operation 220. The treatment plasma exposure time may be greater than or about 1 second, greater than or about 2 seconds, greater than or about 5 seconds, greater than or about 10 seconds, greater than or about 15 seconds, greater than or about 30 seconds, greater than or about 45 seconds, greater than or about 60 seconds, or more. In embodiments, the exposure time of the as-deposited silicon-and-nitrogen-containing material to the treatment plasma may depend on the thickness of the as-deposited material. In embodiments, the exposure time may be greater than or about 0.1 seconds per Angstrom of deposited material (0.1 sec/Å). For example, the exposure time may be greater than or about 0.2 sec/A, greater than or about 0.3 sec/Å, greater than or about 0.4 sec/Å, greater than or about 0.5 sec/Å, greater than or about 0.6 sec/Å, greater than or about 0.7 sec/Å, greater than or about 0.8 sec/Å, greater than or about 0.9 sec/Å, greater than or about 1 sec/Å, greater than or about 2 sec/Å, or more.

The treatment of the silicon-and-nitrogen-containing material on the substrate may be conducted at a treatment temperature that influences the treatment rate of the material. In embodiments, the processing region of the semiconductor processing chamber may be characterized by a treatment temperature less than or about 550° C., less than or about 500° C., less than or about 475° C., less than or about 450° C., less than or about 425° C., less than or about 400° C., less than or about 375° C., less than or about 350° C., or less than or about 300° C., or less.

When a portion of the layer of silicon-and-nitrogen-containing material is formed, a determination may be made whether it completes the formation of the layer of silicon-and-nitrogen-containing material. If the portion of the layer of silicon-and-nitrogen-containing layer material completes the formation of the layer, then another cycle of depositing and treating silicon-and-nitrogen-containing material may not be performed. If the portion of the layer of silicon-and-nitrogen-containing material does not complete the formation of the layer, then another cycle of depositing and treating silicon-and-nitrogen-containing material may begin. As previously discussed, a complete tensile silicon-and-nitrogen-containing layer may be formed when the thickness of the layer reaches greater than or about 10 nm, greater than or about 15 nm, greater than or about 20 nm, greater than or about 25 nm, greater than or about 30 nm, greater than or about 35 nm, greater than or about 50 nm, greater than or about 75 nm, greater than or about 100 nm, greater than or about 125 nm, greater than or about 150 nm, greater than or about 175 nm, greater than or about 200 nm, or more.

In embodiments, operations 205-220 may be formed in one or more cycles to form silicon-and-nitrogen-containing material on the substrate. Embodiments may include numerous cycles of forming material with optional treatment operations performed intermittently as needed or desired. For example, operations 205-220 may be repeated at least two times, at least three times, at least four times, at least five times, at least seven times, at least ten times, or more. Additionally, each cycle may or may not include an optional treatment at optional operation 220.

Method 200 may include depositing one or more additional layers of material on the layer of silicon-and-nitrogen-containing material at optional operation 225. Together with the layer of silicon-and-nitrogen-containing material, the one or more additional layers of material may define a patterning stack. For example, patterning stack may include one or more layers of a silicon-containing material, one or more layers of a carbon-containing material, and one or more additional layers of silicon-and-nitrogen-containing material. The patterning stack may be formed in order to pattern the material underlying the first layer of silicon-and-nitrogen-containing material, such as the alternating pairs of silicon-containing material and silicon-and-germanium-containing material disposed on the substrate. Accordingly, method 200 may include an operation to pattern the uppermost material of the patterning stack prior to etching the underlying material.

After depositing the one or more layers of silicon-and-nitrogen-containing material, substrate may be characterized by a second bowing of the substrate that is less than the first bowing of the substrate. The tensile stress of the one or more layers of silicon-and-nitrogen-containing material may combat the compressive stress of the other materials deposited on the substrate. In embodiments, the second bowing of the substrate may be less than or about 350 μm, less than or about 300 μm, less than or about 275 μm, less than or about 250 μm, less than or about 225 μm, less than or about 200 μm, less than or about 175 μm, less than or about 150 μm, less than or about 125 μm, less than or about 100 μm, less than or about 75 μm, less than or about 50 μm, or less.

Subsequent to forming the patterning stack, method 200 may include etching one or more features through the material underlying the layer of silicon-and-nitrogen-containing material, such as the alternating pairs of silicon-containing material and silicon-and-germanium-containing material disposed on the substrate at optional operation 230. The features may be of any shape or size, such as a hole or trench, and may extend through a portion of the underlying material or all of the underlying material to the substrate. In embodiments, the etching may remove at least a portion of the patterning stack. For example, as the etching progresses into the underlying material, portions, such as entire layers of material, of the patterning stack may be etched as well. As the bow imparted by the underlying material is reduced due to the etching of the features, portions of the patterning stack imparting tensile stress to combat the bow may also be removed. More specifically, the etching may reduce the bowing to the substrate while simultaneously reducing the tensile stress imparted by the patterning stack.

FIGS. 3A-B show cross-sectional views of an exemplary semiconductor structure 300 according to embodiments of the present technology. The exemplary embodiment shown in structure 300 includes a patterning stack including multiple layers of silicon-and-nitrogen-containing material 320, 330, 340 that may be formed by the processing methods according to embodiments of the present technology. In the embodiment shown in FIG. 3A, the structure 300 may also include alternating pairs of a silicon-containing material 310 and a silicon-and-germanium-containing material 315. A first layer of silicon-and-nitrogen-containing material 320 may be formed on the alternating pairs of the silicon-containing material 310 and the silicon-and-germanium-containing material 315. The patterning stack may include a layer of silicon-containing material 325, such as a silicon-and-oxygen-containing material, disposed on the first layer of silicon-and-nitrogen-containing material 320. The layer of silicon-containing material 325 may be, for example, silicon oxide. The patterning stack may include a second layer of silicon-and-nitrogen-containing material 330 disposed on the layer of silicon-containing material 325. The patterning stack may include a layer of carbon-containing material 335, such as an amorphous carbon material, may be disposed on the second layer of silicon-and-nitrogen-containing material 330. The patterning stack may include a third layer of silicon-and-nitrogen-containing material 340 disposed on the layer of carbon-containing material 335.

In the embodiment of structure 300 shown in FIG. 3A, the alternating pairs of the silicon-containing material 310 and the silicon-and-germanium-containing material 315 formed on the substrate may impart a bow to the substrate 305 due to the compressive nature of the materials. In embodiments, the substrate 305 may include greater than 36 alternating pairs of the silicon-containing material 310 and the silicon-and-germanium-containing material 315, such as greater than 40 alternating pairs, greater than 44 alternating pairs, greater than 48 alternating pairs, greater than 50 alternating pairs, greater than 52 alternating pairs, greater than 56 alternating pairs, greater than 60 alternating pairs, greater than 64 alternating pairs, greater than 68 alternating pairs, greater than 72 alternating pairs, or more. A thickness of the individual layers of the alternating pairs, such as the silicon-and-germanium-containing material 315, may be less than or about 30 nm, less than or about 28 nm, less than or about 26 nm, less than or about 24 nm, less than or about 22 nm, less than or about 20 nm, less than or about 18 nm, less than or about 16 nm, less than or about 14 nm, less than or about 12 nm, less than or about 10 nm or less. In embodiments, the thickness of the individual layers of the alternating pairs, such as the silicon-and-germanium-containing material 315, may be greater than or about 5 nm, greater than or about 10 nm, greater than or about 12 nm, greater than or about 14 nm, greater than or about 16 nm, greater than or about 18 nm, greater than or about 20 nm, or more.

As previously discussed, depending on the number of alternating pairs and/or on a thickness of the alternating pairs of the silicon-containing material 310 and the silicon-and-germanium-containing material 315, the substrate 305 may be characterized by a first bowing of greater than or about 150 μm, greater than or about 175 μm, greater than or about 200 μm, greater than or about 225 μm, greater than or about 250 μm, greater than or about 275 μm, greater than or about 300 μm, greater than or about 350 μm, greater than or about 400 μm, greater than or about 450 μm, greater than or about 500 μm, greater than or about 550 μm, greater than or about 600 μm, greater than or about 650 μm, greater than or about 675 μm, greater than or about 700 μm, or more. As previously discussed, downstream operations may be frustrated, and some tools may not be able to process the substrate at increased bowing. Accordingly, tensile silicon-and-nitrogen-containing material may be formed in the patterning stack to combat the bow imparted by the alternating pairs.

In one exemplary embodiment, the structure 300 may include 72 alternating pairs of the silicon-containing material 310 and the silicon-and-germanium-containing material 315. To combat the bowing of the substrate 305, the first layer of silicon-and-nitrogen-containing material 320 may be formed on the alternating pairs. In embodiments, the thickness of the first layer of silicon-and-nitrogen-containing material 320 may be greater than or about 10 nm, greater than or about 15 nm, greater than or about 20 nm, greater than or about 25 nm, greater than or about 30 nm, or more. The layer of silicon-containing material 325 disposed on the first layer of silicon-and-nitrogen-containing material 320 may have a thickness greater than or about 200 nm, greater than or about 300 nm, greater than or about 400 nm, greater than or about 500 nm, or more. The second layer of silicon-and-nitrogen-containing material 330 disposed on the layer of silicon-containing material 325 may further combat the bowing of the substrate 305. In embodiments, the second layer of silicon-and-nitrogen-containing material 330 may be thicker than the first layer of silicon-and-nitrogen-containing material 320. The second layer of silicon-and-nitrogen-containing material 330 may have a thickness of greater than or about 50 nm, greater than or about 75 nm, greater than or about 100 nm, greater than or about 150 nm, greater than or about 200 nm, or more. The layer of carbon-containing material 335 may have a thickness of greater than or about 200 nm, greater than or about 300 nm, greater than or about 400 nm, greater than or about 500 nm, or more. Finally, in the exemplary embodiment shown in FIG. 3A, the third layer of silicon-and-nitrogen-containing material 340 disposed on the layer of carbon-containing material 335 may have a thickness of greater than or about 25 nm, greater than or about 50 nm, greater than or about 75 nm, greater than or about 100 nm, or more. Similar to the second layer of silicon-and-nitrogen-containing material 330, the third layer of silicon-and-nitrogen-containing material 340 may further reduce the bowing of the substrate 305.

FIG. 3B shows structure 300 after etching a feature 345 into the alternating pairs of the silicon-containing material 310 and the silicon-and-germanium-containing material 315. As shown in FIG. 3B, the feature 345 may extend through all the alternating pairs to the substrate 305. However, it is also contemplated that the feature 345 may not extend all the way to the substrate 305. As the silicon-containing material 310 and the silicon-and-germanium-containing material 315 of the alternating pairs is etched, the stress imparted to the substrate to cause the initial bowing may be reduced. Similarly, the etching may remove material of the patterning stack. In the embodiment shown in FIG. 3B, the third layer of silicon-and-nitrogen-containing material 340 and the layer of carbon-containing material 335 may be removed during the etching. Additional or less material of the patterning stack may be removed depending on thicknesses of the materials deposited on the substrate 305 as wells as the etch used to pattern the alternating pairs. As the patterning stack is removed, specifically the silicon-and-nitrogen-containing materials, the tensile stress to combat the compressive stress of the alternating pairs may be reduced. Accordingly, the tensile stress may be reduced while the compressive stress is simultaneously reduced.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. “About” and/or “approximately” as used herein and in the appended claims when referring to a measurable value such as an amount, a temporal duration, and the like, encompasses variations of ±20%, ±10%, ±5%, or ±0.1% from the specified value, as such variations are appropriate to in the context of the systems, devices, circuits, methods, and other implementations described herein. “Substantially” as used herein and in the appended claims when referring to a measurable value such as an amount, a temporal duration, a physical attribute (such as frequency), and the like, also encompasses variations of ±20%, ±10%, ±5%, or ±0.1% from the specified value, as such variations are appropriate to in the context of the systems, devices, circuits, methods, and other implementations described herein.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing deposition precursors to a processing region of a semiconductor processing chamber, wherein the deposition precursors comprise a silicon-containing precursor and a nitrogen-containing precursor, wherein a substrate comprising one or more materials is disposed within the processing region, and wherein the substrate is characterized by a first bowing of the substrate;
generating plasma effluents of the deposition precursors; and
forming a layer of silicon-and-nitrogen-containing material on the substrate, wherein the layer of silicon-and-nitrogen-containing material is characterized by a tensile stress, and wherein, subsequent forming the layer of silicon-and-nitrogen-containing material, the substrate is characterized by a second bowing of the substrate that is less than the first bowing of the substrate.

2. The semiconductor processing method of claim 1, wherein the one or more materials comprise alternating pairs of a silicon-containing material and a silicon-and-germanium-containing material.

3. The semiconductor processing method of claim 2, wherein the layer of silicon-and-nitrogen-containing material is formed on the alternating pairs of the silicon-containing material and the silicon-and-germanium-containing material.

4. The semiconductor processing method of claim 2, wherein the one or more materials comprises greater than 36 alternating pairs of the silicon-containing material and the silicon-and-germanium-containing material.

5. The semiconductor processing method of claim 2, wherein a thickness of the silicon-and-germanium-containing material is greater than or about 5 nm.

6. The semiconductor processing method of claim 1, wherein the first bowing of the substrate is greater than or about 200 μm.

7. The semiconductor processing method of claim 1, further comprising:
treating the layer of silicon-and-nitrogen-containing material with a treatment plasma to increase the tensile stress of the layer of silicon-and-nitrogen-containing material.

8. The semiconductor processing method of claim 1, wherein a thickness of the layer of silicon-and-nitrogen-containing material is greater than or about 50 nm.

9. The semiconductor processing method of claim 1, further comprising:
depositing one or more additional layers of material on the layer of silicon-and-nitrogen-containing material, wherein the one or more additional layers of material define a patterning stack, and wherein the patterning stack comprises a second layer of silicon-and-nitrogen-containing material.

10. The semiconductor processing method of claim 9, wherein the second layer of silicon-and-nitrogen-containing material is characterized by a thickness greater than the thickness of the layer of silicon-and-nitrogen-containing material.

11. The semiconductor processing method of claim 1, further comprising:
etching one or more features through the one or more materials on the substrate, wherein the etching consumes the layer of silicon-and-nitrogen-containing material, and wherein the etching reduces a compressive stress of the substrate and the one or more materials.

12. A semiconductor processing method comprising:
providing a substrate to a processing region of a semiconductor processing chamber, wherein the substrate comprises alternating pairs of a silicon-containing material and a silicon-and-germanium-containing material, and wherein the substrate is characterized by a first bowing of the substrate;
forming a patterning stack comprising one or more layers of material on the alternating pairs of the silicon-containing material and the silicon-and-germanium-containing material, wherein the one or more layers of material comprise at least one layer of silicon-and-nitrogen-containing material characterized by a tensile stress, and wherein, subsequent to forming the patterning stack, the substrate is characterized by a second bowing of the substrate that is less than the first bowing of the substrate; and
etching one or more features through the alternating pairs of the silicon-containing material and the silicon-and-germanium-containing material, wherein the etching removes at least a portion of the patterning stack, and wherein, subsequent to etching, the substrate is characterized by a third bowing of the substrate that is less than the first bowing of the substrate.

13. The semiconductor processing method of claim 12, wherein the substrate comprises greater than 50 alternating pairs of the silicon-containing material and the silicon-and-germanium-containing material.

14. The semiconductor processing method of claim 12, wherein a thickness of the silicon-and-germanium-containing material is less than or about 30 nm.

15. The semiconductor processing method of claim 12, the first bowing of the substrate is greater than or about 275 μm.

16. The semiconductor processing method of claim 12, wherein the patterning stack comprises:
a first layer of silicon-and-nitrogen-containing material disposed on the alternating pairs;
a layer of silicon-containing material disposed on the first layer of silicon-and-nitrogen-containing material;
a second layer of silicon-and-nitrogen-containing material disposed on the layer of silicon-containing material;
a layer of carbon-containing material disposed on the second layer of silicon-and-nitrogen-containing material; and
a third layer of silicon-and-nitrogen-containing material disposed on the layer of carbon-containing material.

17. The semiconductor processing method of claim 12, wherein the second bowing of the substrate is less than or about 175 μm.

18. The semiconductor processing method of claim 12, wherein:
a compressive stress imparted by the alternating pairs of the silicon-containing material and the silicon-and-germanium-containing material reduces while etching the one or more features; and
the tensile stress imparted by the at least one layer of silicon-and-nitrogen-containing material reduces while etching removes at least the portion of the patterning stack.

19. A semiconductor structure comprising:
a substrate;
alternating pairs of a silicon-containing material and a silicon-and-germanium-containing material disposed on the substrate; and
a patterning stack comprising at least one layer of silicon-and-nitrogen-containing material characterized by a compressive stress disposed on the alternating pairs, wherein the semiconductor structure is characterized by a bowing of the substrate of less than or about −200 nm.

20. The semiconductor structure of claim 19, wherein the patterning stack comprises:
a first layer of silicon-and-nitrogen-containing material disposed on the alternating pairs;
a layer of silicon-containing material disposed on the first layer of silicon-and-nitrogen-containing material;
a second layer of silicon-and-nitrogen-containing material disposed on the layer of silicon-containing material;
a layer of carbon-containing material disposed on the second layer of silicon-and-nitrogen-containing material; and
a third layer of silicon-and-nitrogen-containing material disposed on the layer of carbon-containing material.
